(19) United States
(12) Patent Application Publication
(10) Pub. No.: US 2007/0108867 A1
(43) Pub. Date: May 17, 2007

(54) Active suspension component

(76) Inventors: George S. Saloka, Dearbom, MI (US); Tony Godlewski, Rochester Hills, MI (US)

Correspondence Address: FORD GLOBAL TECHNOLOGIES, LLC, FAIRLANE PLAZA SOUTH, SUITE 800, 330 TOWN CENTER DRIVE, DEARBORN, MI, 48126, US

(21) Appl. No.: 11/282,552

(22) Filed: Nov. 17, 2005

(51) Int. Cl. H01L 41/00

(52) U.S. Cl. 310/311

(57) ABSTRACT

The invention is directed to an active suspension component, comprising a composite cross member, a piezoelectric composite material integral with the composite cross member, and control circuitry connected to the piezoelectric composite material for controlling the piezoelectric composite material.

### BACKGROUND OF THE INVENTION

1. Field of Invention

This invention relates to the field of controlling vehicle chassis noise, vibration, and harshness. More specifically, this invention relates to a composite cross member having at least one integral piezoelectric ceramic fiber composite for controlling vehicle chassis noise, vibration, and harshness.

2. Background

Automotive vehicles are subject to a large number of forces, such as transmission noise, that may cause vibrations that are felt and heard by the driver and may decrease driver satisfaction.

Automotive vehicle chassis systems typically include a cross member that extends between the vehicle's chassis and supports the vehicle's transmission. The cross member is known to transmit transmission noise to a vehicle's cabin at resonant frequencies, creating an adverse effect called “boom.” Traditional cross members comprise stamped steel, which does not impede transmission noise. In addition, a stamped steel cross member has a fixed spring rate and therefore cannot be adjusted to accommodate varied driving conditions.

In the past, heavy rubber cross member mount isolators were added to the cross member to isolate the transmitted engine noise. These isolators added undesirable weight and cost to the vehicle chassis system.

Composite cross members have been considered for increased durability and strength, and decreased weight, but composite cross members have not been shown to decrease the amount of noise, vibrations, and harshness transmitted to a driver.

A possible composite mechanism for controlling undesirable vehicle vibrations is embodied in “smart skis” as disclosed in U.S. Pat. No. 6,095,547. Smart skis use a piezoelectric ceramic fiber composite material to actively alter the torsional stability characteristics of a snow ski during use. An embedded microprocessor receives high voltage signals as piezoelectric ceramic fibers, molded into the ski, are flexed due to torsional changes such as bending and vibration. The microprocessor redirects the high voltage signal back to the piezoelectric ceramic fibers. Upon receiving the high voltage signal, the piezoelectric fibers straighten, thus increasing the torsional stability of the ski. The electrical circuit is enclosed in the ski, and does not require any additional external power.

Physical properties of piezoelectric materials include the ability to change shape when an electric field is applied. Conversely, electric voltage is generated when the material is stretched or compressed, for example due to vibration. Piezoelectric material was formerly available in a bulk ceramic form, which is commonly used in sensors and actuators. However, a new form of piezoelectric material includes piezoelectric ceramic fiber composites. Unlike the bulk form of the material, the ceramic fiber composite is lightweight and flexible, and is fabricated, for example, from individual cell strands (from 5 to 250 microns in length) that are woven in a cloth-like fashion having string-like or ribbon-like fibers. When a voltage is applied to the piezoelectric ceramic fiber composite, the sample increases in length due to the basic characteristics of the piezoelectric material.

It is possible to bond the piezoelectric ceramic fiber composite to a substrate of another material to create a new material system. When a voltage is applied to the piezoelectric ceramic fiber composite, the composite will try to expand; however, the bonded substrate will bend or resist bending to create a stiffer system. If the system is flexed or stress, such as during vehicle vibration, a voltage is produce by the system.

### BRIEF SUMMARY OF THE INVENTION

In one embodiment, the invention is directed to an active suspension component, comprising a composite cross member, a piezoelectric composite material integral with the composite cross member, and control circuitry connected to the piezoelectric composite material for controlling the piezoelectric composite material.

In another embodiment, the invention is directed to a method of manufacturing an active suspension component, comprising forming a composite cross member with an integral piezoelectric composite material, and attaching control circuitry to the piezoelectric composite material for controlling the piezoelectric composite material.

In yet another embodiment, the invention is directed to a method for damping vibrations, comprising providing a composite cross member, integrating a piezoelectric composite material with the composite cross member, and controlling the piezoelectric composite material to dampen vibrations.

Further features of the present invention, as well as the structure of various embodiments of the present invention are described in detail below with reference to the accompanying drawings.

### BRIEF DESCRIPTION OF THE DRAWINGS

The accompanying drawings, which are incorporated herein and form part of the specification, illustrate the present invention and together with the description, further serve to explain the principles of the invention and to enable a person skilled in the pertinent art to make and use the invention. In the drawings, like reference numbers indicate identical or functionally similar elements.

FIG. 1 illustrates how piezoelectric materials work.

FIG. 2 is a perspective view of an embodiment of a piezoelectric ceramic fiber composite material in accordance with the invention.

FIG. 3 is a perspective view of an active suspension component that would be formed integral with the composite material shown in FIG. 2.

FIG. 4 illustrates basic principles that can be used for controlling an active suspension component of the invention.

### DETAILED DESCRIPTION OF THE INVENTION

The present invention provides an automotive application for piezoelectric ceramic fiber composites used with composite cross members. Composite cross members comprise composite material, which can include any strong, lightweight material developed in a laboratory, usually with fibers of more than one kind being bonded together chemically. An active suspension component, such as a composite cross member with piezoelectric ceramic fiber composite materials embedded therein, could replace the steel cross member and provide the ability for self-powered, enhanced control of vehicle vibrations without adding undesirable cost and weight. This active suspension component could provide reduced transmission noise, reduced vehicle body shake for improved ride characteristics, and a lower component weight.

Composite cross members can be manufactured, for example, using structural reaction injection molding (SRIM), foam cores, braided performing, and heat shields. Manufacturing composite cross members requires consideration and determination of the proper: (1) liquid molding process; (2) resin selection; (3) core type; (4) fiber perform; (5) heat shield; and (6) mold design. The SRIM process allows for rapid cure rates, and the resulting faster cycle times reduces the number of molds needed to manufacture desired volumes. In SRIM processes, a glass fiber preform is placed in a metal mold and low viscosity resin is rapidly injected. The resin quickly impregnates the fibers and rapidly crosslinks to form a rigid polymer matrix. Using a two-piece steel mold provides even temperature distribution across the face of the mold and allows for geometry and gate changes. Mold heat accelerates the reaction.

The SRIM process and vehicle temperature requirements can narrow the resin selection for manufacturing the composite cross member. Key issues for resin selection include high temperature performance, cost, and processing. Other characteristics taken into consideration are creep behavior, fatigue strength, chemical resistance, and glass wetability. As an example, an elevated-temperature isocyanurate urethane resin system can be used.

A foam core acts as a mandrel for winding of a fiber reinforcement preform for the cross member. The core controls the thickness of the molded laminate and provides a small degree of cross member stiffness. As an example, a two-component polyurethane foam system can be directly injected into aluminum molds to produce a suitable core. The aluminum molds are heated and maintain a uniform temperature across their face.

Fiber preforming is the shaping of dry glass fibers into the net shape of the molded part. Common forms of preforming are hand lay-up, thermoformable stamped mats, braiding, spray-up, or a slurry process. Braiding can be advantageous because it allows minor changes in the fiber architecture without affecting the preforming system. Braiding can also eliminate joints that can be prevalent in other preforming processes. In preforming, biased and axial fiberglass rovings can be braided directly onto the foam cores. Changes to the roving sizes allow the strength and stiffness to be tailored to the vehicle needs. The glass volume percentage can also be tailored by, for example, adjusting the angle of the braid, thus controlling the SRIM flow process by selectively varying permeability.

Heat shields should remain intact on the cross member during all foreseeable operating conditions.

The active suspension component is a composite cross member that includes an embedded piezoelectric fiber composite operating similarly to the smart ski. The piezoelectric fiber composite preferably is a ceramic fiber composite. The smart ski utilizes ACI's VSSP ceramic-fiber technology, which can produce flexible fiber from almost any material. The fibers are assembled into composites that take advantage of ceramics' beneficial electric, chemical, and mechanical properties and mitigate weight and brittleness concerns.

Piezoelectric ceramic fiber composites can comprise many different ceramic chemistries, including lead zirconate titanate (PZT), titanium dioxide (conductive and non-conductive), tin oxide, silicon carbide, several aluminas, hydroxyapatite, yttrium aluminum garnet (YAG), lithium aluminate, and zirconium diboride.

In use, as a result of vibrations, the piezoelectric fibers generate electricity of high potential and low current. The electricity is stored and released back to the fibers, as needed and preferably in real time, in the optimal phase and waveform for most efficient damping to control noise, vibration, and harshness. In a preferred embodiment of the invention, energy harvesting can be used to collect waste mechanical energy produced by the piezoelectric fibers and provide that energy to perform a function (damping) totally independent of an outside control or source of power. Thus, in a preferred embodiment of the invention, the active suspension component controls noise, vibration, and harshness without the need for an external power source. Energy harvesting devices are inexpensive, and their operation is free.

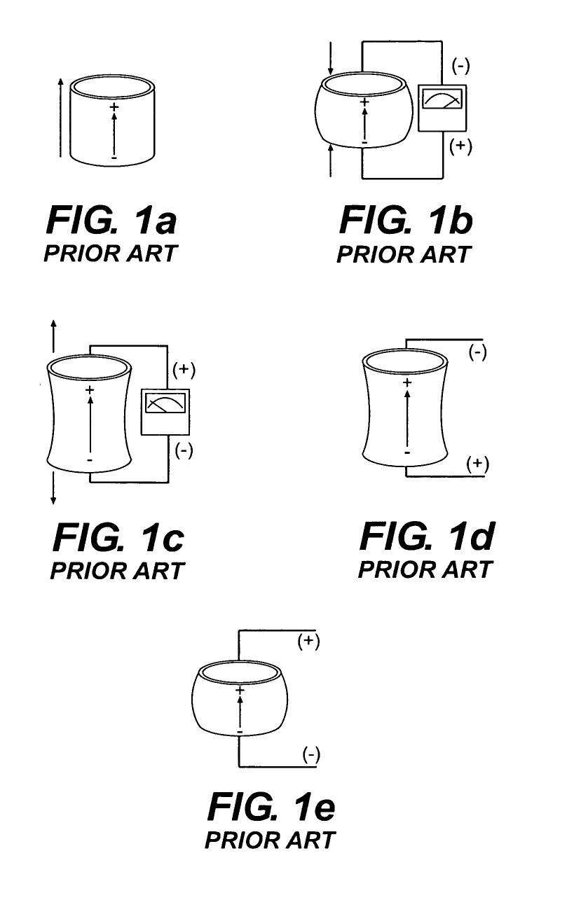

FIG. 1 illustrates the generator and motor actions of a piezoelectric element. When subjected to a mechanical force, piezoelectric elements become electrically polarized. Tension and compression of piezoelectric elements lengthen and shorten the elements, respectively, generating voltages of opposite polarity, and in proportion to the applied force. Conversely, when subjected to an electric field, piezoelectric elements lengthen or shorten according to the polarity of the electric field, and in proportion to the strength of the field.

In accordance with FIG. 1, sub-figure (a) illustrates a piezoelectric element after polarization, with the poling voltage extending in the direction of the arrow. Subfigures (b) and (c) illustrate the generator action of a piezoelectric element. Subfigure (b) shows that when the element is compressed according to the arrows, a voltage is generated with the same polarity as the poling voltage. Subfigure (c) shows that when the element is stretched according to the arrows, a voltage is generated with a polarity opposite that of the poling voltage. Subfigures (d) and (e) illustrate the motor action of a piezoelectric element. Subfigure (d) shows that when a voltage is applied to the element that has the same polarity as the element's poling voltage, the element stretches or lengthens. Subfigure (e) shows that when a voltage is applied to the element that has a polarity opposite from the element's poling voltage, the element compresses or shortens.

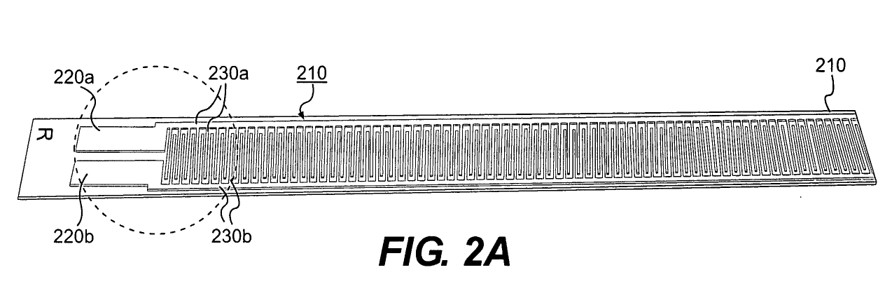

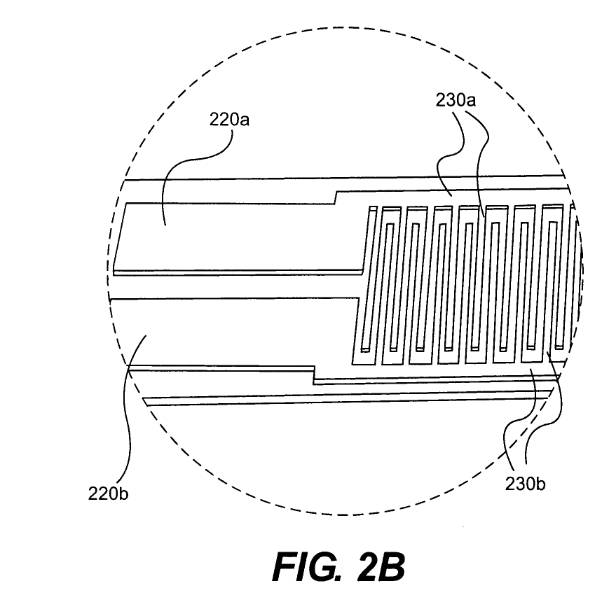

FIG. 2 illustrates an embodiment of a section of piezoelectric ceramic fiber composite material 200 encased in a clear plastic coating 210. Two electrodes 220a, 220b are attached to the piezoelectric ceramic fiber composite material 200. The electrodes 220a, 220b are metallic connections, preferably soldered to the piezoelectric ceramic fiber composite material, that allow voltage to be applied to control the piezoelectric ceramic fiber composite material. The electrodes 220a, 220b have a predetermined polarity. By forming the piezoelectric ceramic fiber composite material into a string-like or ribbon-like fiber 230a, 230b as illustrated, the material becomes flexible, lightweight, and inexpensive. Ribbon-like and string-like is defined to include fibers having a geometry to allow the overall piezoelectric ceramic fiber composite material to be flexible, as well as fibers that have a string-like or ribbon-like appearance. Because the material is flexible, it can change shape (i.e., flex) when a voltage is applied. In addition, when the piezoelectric ceramic fiber composite material 200 is bent or flexed during normal operation of the vehicle, it generates a voltage that can be stored and applied later.

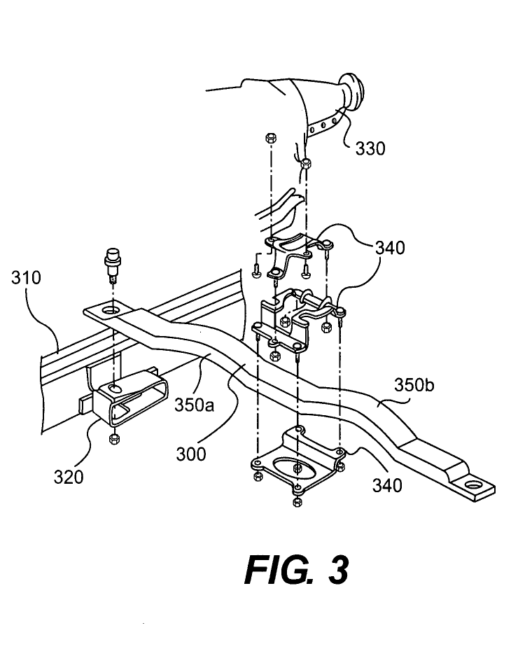

FIG. 3 illustrates an active suspension component of the present invention, including a composite cross member 300 mounted between side portions of the vehicle's chassis 310. The cross member 300 is preferably mounted to the chassis using cross member mounts 320. The cross member 300 is located under a vehicle's transmission 330 and supports the transmission 330. The transmission 330 is preferably mounted to the cross member 300 via a transmission mount assembly 340.

In the embodiment of the invention illustrated in FIG. 3, the cross member 300 preferably has two raised portions 350a, 350b, between which lies an area for seating the transmission 330. The raised portions 350a, 350b are known to provide a cradle for the transmission 330.

In a preferred embodiment of the invention, the cross member 300 comprises a composite material such as a polymer composite material type composed of glass fibers, calcium carbonate, polyester resin, and various additives, but may be made of other composites that provide suitable strength, durability, and cost-effectiveness.

In a preferred embodiment of the invention, one or more sections of piezoelectric ceramic fiber composite material 200 are embedded within the composite cross member 300. For example, one or more sections of piezoelectric ceramic fiber composite material 200 can extend within the composite cross member 300 along substantially the entire length of the cross member 300. Alternatively, one or more sections of piezoelectric ceramic fiber composite material 200 can be placed at specified locations along the cross member 300 where control of physical properties of the cross member 300 is most desirable. Still further, at least one section of piezoelectric ceramic fiber composite material 200 can extend within the composite cross member along substantially the entire length of the cross member 300, with additional sections of piezoelectric ceramic fiber composite material 200 being added where control of physical properties of the cross member 300 is most desirable. The present invention contemplates a single section of piezoelectric ceramic fiber composite material 200 having a thickness sufficient to control the physical properties of the cross member 300, and also contemplates any number of stacked layers of piezoelectric ceramic fiber composite material 200 sufficient to control the physical properties of the cross member 300.

In another embodiment of the inventions, one or more sections of piezoelectric ceramic fiber composite material 200 may be adhered to the exterior of the composite cross member, rather than being embedded therein.

The embedded piezoelectric ceramic fiber composite material 200 provides the cross member 300 with an adjustable spring rate. By varying the voltage applied to the piezoelectric ceramic fiber composite material 200, the spring rate of the cross member 300 can be adjusted to minimize vehicle noise, vibrations, and harshness.

The control circuitry for the active suspension component of the present invention comprises, for example, a microprocessor according to a number of known variations. The microprocessor receives high voltage signals as the fibers 230a, 230b of the piezoelectric ceramic fiber composite material 200 are flexed due to torsional changes such as bending and vibration. In response, the microprocessor redirects a high voltage signal back to the piezoelectric ceramic fibers 230a, 230b. Upon receiving the high voltage signal from the microprocessor, the piezoelectric ceramic fibers straighten, increasing the torsional stability of the cross member 300. Thus, the microprocessor controls energy storage and release of energy back to the fibers 230a, 230b, preferably in an optimal phase and wave form for effective and efficient damping to control vehicle chassis noise, vibration, and harshness. The microprocessor can be programmed in a number of known ways to provide effective and efficient damping, for example by producing a cancellation vibration. Cancellation vibrations include vibrations having an amplitude and frequency that cancels out an unwanted vibration.

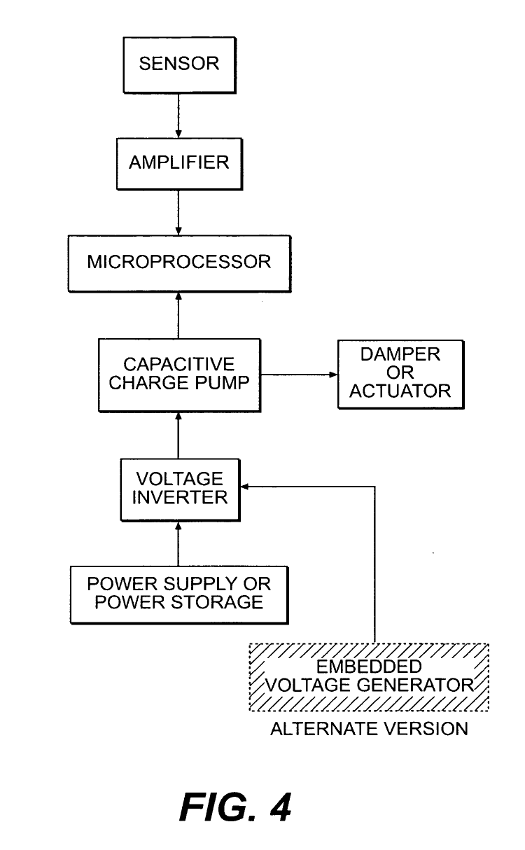

The block diagram of FIG. 4 illustrates basic principals that can be used for controlling the active suspension component of the invention. A sensor senses flexure of the cross member (e.g., due to chassis noise, vibration, and/or harshness) and produces a signal indicative thereof. In a preferred embodiment of the invention, the piezoelectric ceramic fiber composite material 200 acts as the sensor. An amplifier translates the sensor signal to a signal compatible with the microprocessor. The signal is received by the microprocessor. Based on the signal, the microprocessor modulates (controls) a capacitive charge pump that activates the piezoelectric ceramic fiber composite material 200 to act as an actuator or damper. The capacitive charge pump increases the amplitude of an inverter to the high voltage required to activate the piezoelectric ceramic fiber composite material 200. The piezoelectric ceramic fiber composite material 200 may require, for example, approximately 2000 volts to act effectively as a damper or actuator. If the power supply were, for example, the vehicle's 12 volt battery, the capacitive charge pump would increase the voltage accordingly.

The present invention contemplates using an external power source to supply voltage for controlling the piezoelectric ceramic fiber composite material 200, or a closed system where power from the piezoelectric ceramic fiber composite material 200 is harvested and used for damping. Alternatively, power harvested from the piezoelectric ceramic fiber composite material 200 can be the primary source and an external power source can be used as backup, or vice versa.

Activating the piezoelectric ceramic fiber composite material 200 is similar to charging a capacitor. The voltage inverter receives power from a power supply and supplies a voltage to the capacitive charge pump. The voltage supplied to the capacitive charge pump is preferably AC. Thus, if the power source is a DC power source, the voltage inverter must convert DC voltage to AC voltage. The power supply may comprise, for example, the vehicle's 12-volt battery or a storage device, such as a capacitor, that receives power harvested from the piezoelectric ceramic fibers.

The invention contemplates the microprocessor, amplifier, capacitive charge pump, voltage inverter, and sensor being embedded in the composite cross member 300 or being external to the cross member 300. These elements are electrically connected to the piezoelectric ceramic fiber composite 200. If the microprocessor, amplifier, capacitive charge pump, voltage inverter, and sensor are not embedded in the composite cross member 300, they may alternatively be located in the engine compartment of the vehicle. If the sensor is the piezoelectric ceramic fiber composite 200, it is embedded in or attached to the cross member 300, so that it is integral with the cross member 300.

The piezoelectric ceramic fiber composite 200 (see FIG. 2) straightens when a voltage is applied to the piezoelectric electrodes 220a, 220b of the piezoelectric ceramic fiber composite 200, adjusting the spring rate (or torsional stability) of the cross member as needed. The adjustable spring rate (or torsional stability) of the active composite cross member allows the cross member to control noise, vibration, and/or harshness conditions produced by the engine and transmission speed. The piezoelectric ceramic fiber composite 200 can also provide effective and efficient damping by producing a cancellation vibration. The active suspension component of the invention preferably also reduces vehicle shake and improves ride characteristics.

The present invention contemplates piezoelectric ceramic fiber composite material acting as both an actuator/damper and a sensor. Alternatively, the sensor may be a strain gauge that varies in value as a function of flexure of the cross member. The sensor detects flexure of the cross member (e.g., due to chassis noise, vibration, and/or harshness) and supplies a signal to the microprocessor.

What is claimed is:

1. An active suspension component, comprising:
a composite cross member;
a piezoelectric composite material integral with the composite cross member; and
control circuitry connected to the piezoelectric composite material for controlling the piezoelectric composite material.

2. The device of claim 1, wherein the piezoelectric composite material is embedded within the cross member.

3. The device of claim 1, wherein the piezoelectric composite material comprises fibers.

4. The device of claim 3, wherein the piezoelectric composite material includes ribbon-like or string-like piezoelectric fibers.

5. The device of claim 3, wherein, when the control circuitry sends a voltage to the piezoelectric composite material, the piezoelectric fibers produce a cancellation vibration.

6. The device of claim 3, wherein, when the control circuitry sends a voltage to the piezoelectric composite material, the piezoelectric fibers straighten, increasing the torsional stability of the cross member.

7. The device of claim 1, wherein the piezoelectric composite material produces a voltage when flexed due to a torsional change.

8. A method of manufacturing an active suspension component, comprising:
forming a composite cross member with an integral piezoelectric composite material; and
attaching control circuitry to the piezoelectric composite material for controlling the piezoelectric composite material.

9. The method of claim 8, wherein the piezoelectric composite material is embedded within the composite cross member.

10. The method of claim 8, wherein the piezoelectric composite material comprises piezoelectric ceramic fibers.

11. The method of claim 10, wherein the piezoelectric ceramic fibers are ribbon-like or string-like fibers.

12. The method of claim 11, wherein, when the control circuitry sends a voltage to the piezoelectric composite material, the piezoelectric fibers produce a cancellation vibration.

13. The method of claim 11, wherein, when the control circuitry sends a voltage to the piezoelectric composite material, the piezoelectric fibers straighten, increasing the torsional stability of the composite cross member.

14. The method of claim 8, wherein the piezoelectric composite material produces a voltage when flexed due to torsional change.

15. A method for damping vibrations, comprising:
providing a composite cross member;
integrating a piezoelectric composite material with the composite cross member; and
controlling the piezoelectric composite material to dampen vibrations.

16. The device of claim 15, wherein the piezoelectric composite material is embedded within the cross member.

17. The method of claim 15, wherein the piezoelectric composite material includes piezoelectric ceramic fibers.

18. The method of claim 17, wherein controlling the piezoelectric composite material comprises sending a voltage to the piezoelectric composite material so that the piezoelectric fibers produce a cancellation vibration.

19. The method of claim 17, wherein controlling the piezoelectric composite material comprises sending a voltage to the piezoelectric composite material to increase the torsional stability of the cross member.

20. The method of claim 15, wherein the piezoelectric composite material produces a voltage when flexed due to a torsional change.
